(19) United States
(12) Patent Application Publication
(10) Pub. No.: US 2020/0357996 A1
(43) Pub. Date: Nov. 12, 2020

(54) Multi-Layered Structure Having a Barrier Layer

(71) Applicant: Arm Limited, Cambridge (GB)

(72) Inventors: Ming He, San Jose, CA (US); Paul Raymond Besser, Sunnyvale, CA (US); Jolanta Bozena Celinska, Colorado Springs, CO (US)

(21) Appl. No.: 16/408,452

(22) Filed: May 9, 2019

(51) Int. Cl. H01L 49/00

(52) U.S. Cl. CPC H01L 49/003

(57) ABSTRACT

Various implementations described herein are directed to a device having a multi-layered structure that may be formed on a substrate. The multi-layered structure may have a switching layer, and the switching layer may be formed with correlated electron material (CEM). The multi-layered structure may have at least one barrier layer, and the at least one barrier layer may be referred to as at least one hydrogen barrier layer.

### BACKGROUND

This section is intended to provide information relevant to understanding various technologies described herein. As the section's title implies, this is a discussion of related art that should in no way imply that it is prior art. Generally, related art may or may not be considered prior art. It should thus be understood that any statement in this section should be read in this light, and not as any admission of prior art.

Generally, correlated electron material (CEM) is sensitive to hydrogen. At elevated temperature, hydrogen molecules or hydrogen radicles from hydrogen plasma can react with metallic oxides and produce a reaction byproduct that can increase device leakage and/or sometimes cause device shorts. In addition, the reaction byproduct may have gaseous water moisture that can cause delamination within a process integration stack.

### BRIEF DESCRIPTION OF THE DRAWINGS

Implementations of various metal layout techniques are described herein with reference to the accompanying drawings. It should be understood, however, that the accompanying drawings illustrate only various implementations described herein and are not meant to limit embodiments of various techniques described herein.

FIGS. 1-6 illustrate various diagrams of a multi-layered structure formed on a substrate layer in accordance with implementations described herein.

FIG. 7 illustrates a diagram of the multi-layered structure having multiple barrier layers in accordance with various implementations described herein.

FIGS. 8A-8B illustrate various diagrams related to correlated electron material (CEM) in accordance with various implementations described herein.

### DETAILED DESCRIPTION

Various implementations described herein are directed to various schemes and techniques for providing a multi-layered structured device having one or more barrier layers for inhibiting hydrogen penetration and/or interaction with other layers. For instance, various schemes and techniques described herein refer to a semiconductor processing methodology for providing one or more hydrogen barriers for correlated electron random access memory (CeRAM) integration. In reference to enabling CeRAM integration, the various schemes and techniques described herein are directed to inserting one or more hydrogen barriers into the CeRAM integration stack to protect the CEM switching material, such as, e.g., nickel-oxide doped with carbonyls (NiOC), against hydrogen (H2) reduction. Also, in reference to CeRAM integration, the various schemes and techniques described herein are directed to CeRAM memory cell deposition, patterning, and/or upper metal interconnection fabrication.

Generally, conventional metallic or dielectric films do not typically stop diffusion of small hydrogen (H2) molecules or hydrogen (H) radicals. In some implementations, to assist with protecting the switching layer (NiOC) of the CeRAM device stack from hydrogen, the various schemes and techniques described herein insert a hydrogen barrier between a top iridium (Ir) plate and a top titanium-nitride (TiN) layer. In this way, some potential hydrogen molecules and/or radicals may be blocked from interacting with the switching material (NiOC) using one or more hydrogen barriers. Also, after CeRAM stack patterning, potential hydrogen may be blocked away from the switching layer (NiOC).

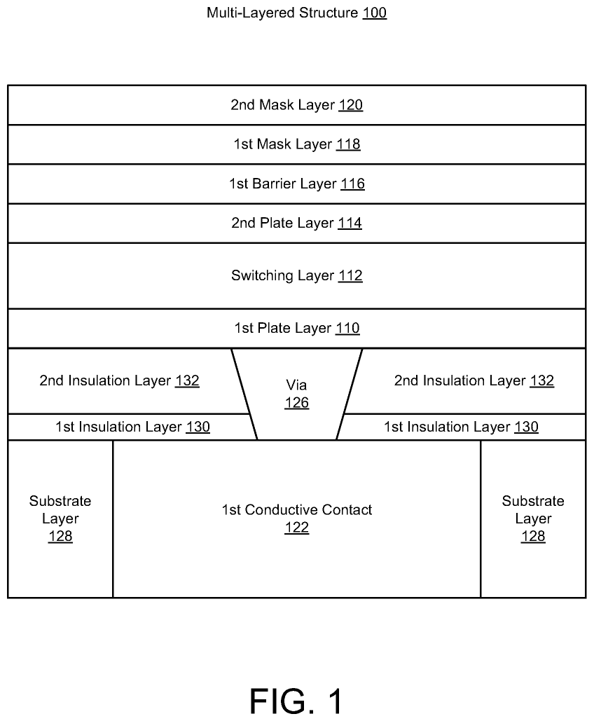

Various implementations of schemes and techniques for providing a multi-layered structure having a switching layer of correlated electron material (CEM) and one or more hydrogen barrier layers will now be described in FIGS. 1-7 and 8A-8B.

FIGS. 1-6 illustrate diagrams of a multi-layered structure 100 formed on a substrate layer 128 in accordance with implementations described herein.

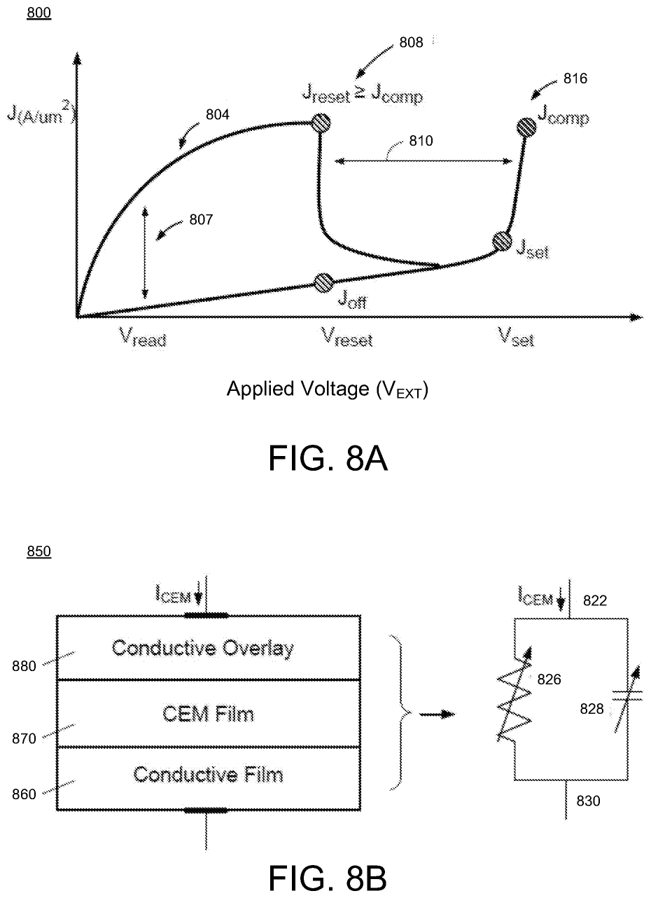

As shown in FIG. 1, the multi-layered structure 100 is formed on the substrate layer 128, and the multi-layered structure has a switching layer 112 and at least one barrier layer 116 as a first barrier layer. FIG. 1 may refer to a deposition operation or similar event in a semiconductor fabrication process that may be used to form the multi-layered structure 100. In some instances, the switching layer 112 is formed with correlated electron material (CEM). As described herein, the multi-layered structure 100 may be referred to as a switch structure, such as, e.g., a memory element having a memory switching structure using CEM type switching material. For instance, the multi-layered structure 100 may be implemented as a correlated electron random access memory (CeRAM) structure. Further description and scope related to CEM and the switching structure associated therewith are described in greater detail herein below in reference to FIGS. 8A-8B.

The substrate layer 128 includes a first contact that is formed as a first conductive contact 122, and the multi-layered structure 100 is formed above the first conductive contact 122. In some instances, the first conductive contact 122 may be formed of a metal material or some other conductive material. Also, the multi-layered structure 100 may include one or more insulation layers (e.g., 130, 132) formed on the substrate layer 128 above the first conductive contact 122. For instance, the one or more insulation layers (e.g., 130, 132) may include a first insulation layer 130 formed on the substrate layer 128, and the one or more insulation layers (e.g., 130, 132) may include a second insulation layer 132 formed on the first insulation layer 130. In some instances, the insulation layers 130, 132 may be formed of an insulation material, such as, e.g., fluorosilicate glass (FSG) or some other insulation type material, such as, e.g., silicon-oxide (SiO) or similar. The multi-layered structure 100 may include at least one via 126 formed in the one or more insulation layers 130, 132. The via 126 is conductive, and the via 126 is formed on the first conductive contact 122 so as to be in direct contact with the first conductive contact 122. In some instances, the via 126 may be formed of a metal material or some other conductive material.

The multi-layered structure 100 further includes a first plate layer 110 that is formed on the second insulation layer 132 above the via 126. The first plate layer 110 may be referred to as a bottom plate (BP) or a lower plate. The first plate layer 110 may include a conductive type of material, such as, e.g., a metal based material, and as such, the first plate layer 110 may be referred to as a bottom metal plate or a lower metal plate. In some instances, the first plate layer 110 may be formed of an iridium (Ir) material or some other similar material, such as, e.g., tantalum nitride (TaN) or titanium-nitride (TiN). In some implementations, the first plate layer 110 may include multiple metal layers, e.g., a TaN layer may be deposited as an adhesion layer, then an Ir layer may be deposited in the TaN layer, or a Pt electrode layer may be deposited on the TaN layer, which may have contact with the CEM layer 112.

The multi-layered structure 100 further includes the switching layer 112 that is formed on the first plate layer 112 above the via 126. The switching layer 112 may be a transition metal oxide (TMO) layer that includes correlated electron material (CEM), which may be used as a memory switching material. In some instances, the switching layer 112 may include a nickel-oxide (NiO) material that is doped with carbonyls (C) to provide an NiOC type material, which may be referred to as carbon (C) doped nickel-oxide (NiO).

The multi-layered structure 100 further includes a second plate layer 114 that is formed on the switching layer 112 above the via 126. The second plate layer 114 may be referred to as a top plate (TP) or an upper plate. The second plate layer 114 may include a conductive type of material, such as, e.g., a metal based material, and as such, the second plate layer 114 may be referred to as a top metal plate or an upper metal plate. In some instances, the second plate layer 114 may be formed of an iridium (Ir) material or other similar material, such as, e.g., tantalum nitride (TaN) or titanium-nitride (TiN).

The multi-layered structure 100 further includes the first barrier layer 116 that is formed on the second plate layer 114 above the via 126. The first barrier layer 116 may include a conductive hydrogen barrier layer that inhibits hydrogen (H2) penetration into or interaction with one or more other layers of the multi-layered structure 100. The first barrier layer 116 may be referred to as a conductive hydrogen (H2) barrier. Thus, the first barrier layer 116 may include a conductive barrier layer, and the conductive barrier layer may include at least one of titanium-nitride (TiN), titanium-aluminum-nitride (TiAlN), tin-oxide (SnO2), and indium-tin-oxide (ITO or tin-doped indium oxide). In some instances, the first barrier layer 116 may be formed by chemical vapor deposition (CVD) for good sidewall coverage. In other instances, the first barrier layer 116 may be formed by physical vapor deposition (PVD). The first barrier layer 116 may be formed to have a thickness between 5 and 50 nanometers (nm).

The multi-layered structure 100 further includes a first mask layer 118 that is formed on the first barrier layer 116 above the via 126. In some instances, the first mask layer 118 may be formed of a titanium nitride (TiN) material or some other similar material.

The multi-layered structure 100 further includes a second mask layer 120 that is formed on the first mask layer 118 above the via 126. In some instances, the second mask layer 118 may be referred to as a hard mask layer, and the second mask layer 118 may be formed of an oxide based material or some other similar material. In some implementations, the first mask layer 118 and the second mask layer 120 may be incorporated into a single mask layer (instead of two mask layers), and If there is only one mask layer, then may be a TiN hardmask layer.

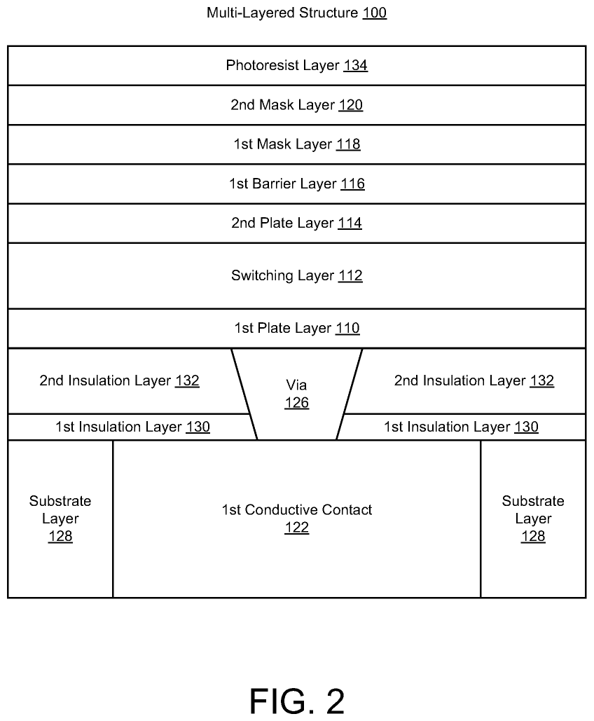

As shown in FIG. 2, a photo-resist layer 134 may be formed on the second mask layer 134 of the multi-layered structure 100. Also, the photo-resist layer 134 may be formed above the via 126. In some instances, FIG. 2 may refer to a lithography operation or similar event in a semiconductor fabrication process that may be used to form the multi-layered structure 100.

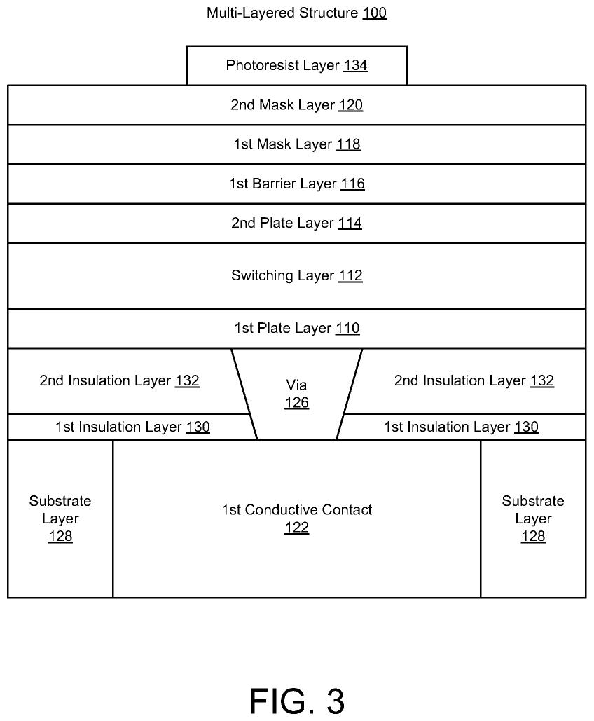

As shown in FIG. 3, the photo-resist layer 134 may be etched to overlie a portion of the multi-layered structure 100 above the via 126. In some instances, FIG. 3 may refer to an exposure operation or similar event in a semiconductor fabrication process that may be used to form the multi-layered structure 100.

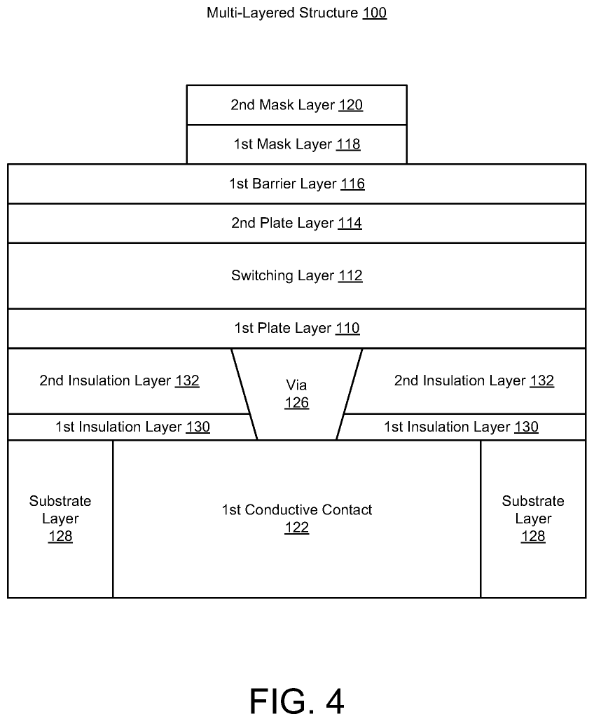

As shown in FIG. 4, the photo-resist layer 134 may be used to etch the first mask layer 118 and the second mask layer 120 to overlie a portion of the multi-layered structure 100 above the via 126. After etching, the photo-resist layer 134 may be removed. In some instances, FIG. 4 may refer to a patterning (or etching) operation or similar event in a semiconductor fabrication process that may be used to form the multi-layered structure 100, wherein the photo-resist layer 134 is used to pattern the first mask layer 118 and the second mask layer 120.

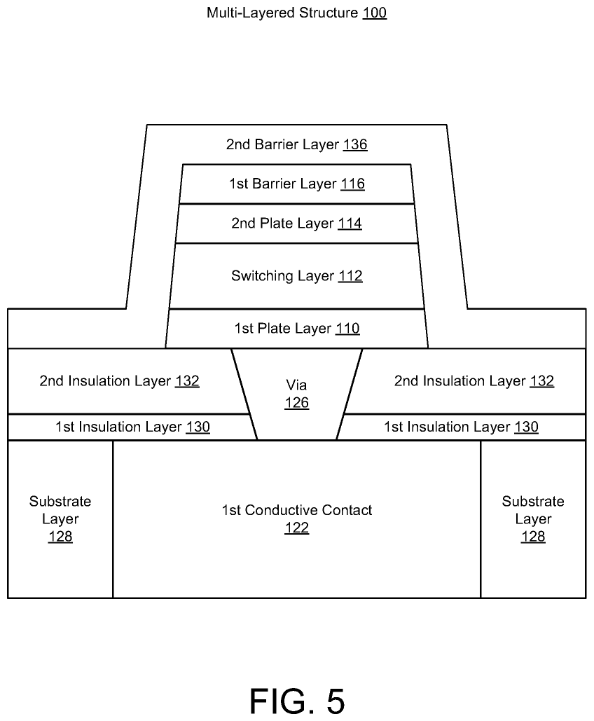

As shown in FIG. 5, multiple layers 110, 112, 114, 116 of the multi-layered structure 100 may be etched to overlie a portion of the multi-layered structure 100 above the via 126, wherein hydrogen-free etching is used. Also, as shown in FIG. 5, a second barrier layer 136 may be formed to overlie the multiple layers 110, 112, 114, 116, 118, 120 of the multi-layered structure 100 above the via 126. As shown, a device stack of the multiple layers 110, 112, 114, 116 may be etched to the second insulation layer 132. Also, in this instance, the second barrier layer 136 may be formed to continuously overlie the second insulation layer 132 along with the multiple layers 110, 112, 114, 116. In some instances, one or more of the mask layers 118, 120 may not be completely removed during etching. Also, in some instances, FIG. 5 may refer to another patterning operation or similar event in a semiconductor fabrication process that may be used to form the multi-layered structure 100, wherein the multiple layers 110, 112, 114, 116, 118, 120 are patterned into the device stack, which may be referred to as a CeRAM stack. In various instances, the second barrier layer 116 may be formed to have a thickness between 5 and 50 nanometers (nm).

In some implementations, the first barrier layer 116 may be formed as a conductor with a conductive material, and the multi-layered structure 100 includes the second barrier layer 136 that may be formed as an insulator with an insulation material. In this instance, the second barrier layer 136 may be formed over the multi-layered structure 100 as an insulator that is used for encapsulating the multi-layered structure 100. The second barrier layer 136 may be referred to as an insulating hydrogen (H2) barrier. The second barrier layer 136 may be formed with an insulator type material comprising at least one of strontium-tantalate (SrTa2O6), bismuth-tantalate (Bi2Ta2O8), tantalum-oxide (Ta2O5), titanium-oxide (TiO2), zirconium-oxide (ZrO2), and aluminum-oxide (Al2O3). In some instances, the second barrier layer 136 may be formed with chemical vapor deposition (CVD) for good sidewall coverage. In other instances, the second barrier layer 136 may be formed by physical vapor deposition (PVD).

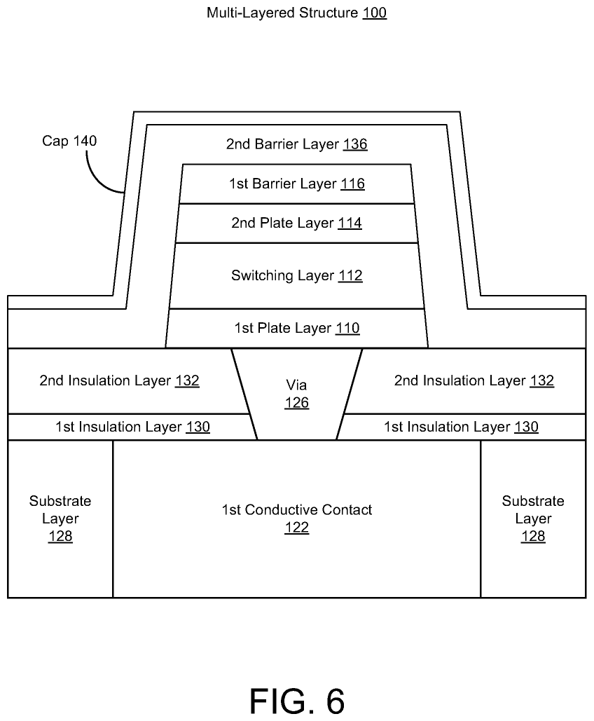

As shown in FIG. 6, an encapsulation layer 140 (or cap layer) may be formed to overlie the second barrier layer 136 and the device stack of the multiple layers 110, 112, 114, 116 of the multi-layered structure 100 above the via 126. In some instances, FIG. 6 may refer to an encapsulation operation or some similar event in a semiconductor fabrication process that may be used to encapsulate the multi-layered structure 100 with the cap layer 140. For instance, the multiple layers 110, 112, 114, 116 and the second barrier layer 136 of the device stack (such as, e.g., the CeRAM stack) may be encapsulated with an encapsulating material such as, e.g., silicon-nitride (SiN).

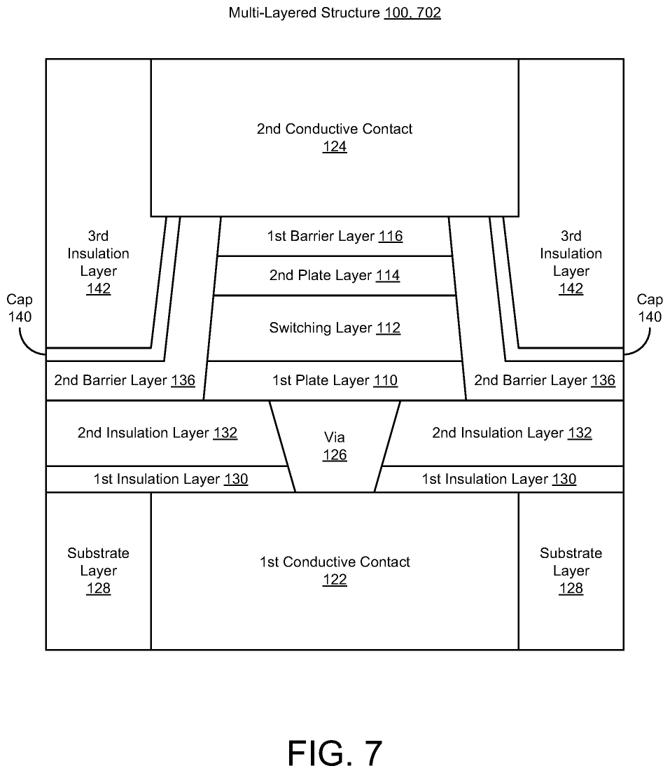

FIG. 7 illustrates a structural diagram of a device 702 having the multi-layered structure 100 as a switching structure with the multiple barrier layers 116, 136 in accordance with various implementations described herein.

As shown in FIG. 7, the multi-layered structure 100 is formed on the substrate layer 128, and the multi-layered structure 100 has the switching layer 112 and multiple barrier layers 116, 136. As described herein, the switching layer 112 may be formed with correlated electron material (CEM). The substrate layer 128 includes the first contact that is formed as the first conductive contact 122, and the multi-layered structure 100 is formed above the first conductive contact 122. The multi-layered structure 100 may include a second contact that is formed as a second conductive contact 124, and also, the second conductive contact 124 may be formed above the first mask layer 118.

As described herein, the device CeRAM stack of the multiple layers 112, 114, 116 are etched to the second barrier layer 132, and the second barrier layer and the cap layer 140 are formed to overlie the device CeRAM stack. In some instances, a hydrogen-free etching is used. The multi-layered structure 100 may include a third insulation layer 142, and the second conductive contact 124 may be formed in the third insulation layer 142. In some implementations, the third insulation layer 142 may be formed to overlie the cap layer 140, and a trench may be etched in the insulation layer to form a recess for depositing the second conductive contact 124. As shown in FIG. 7, the trench may be etched to remove a portion of the second barrier layer 136, a portion of the cap layer 140, and the second mask layer 120 prior to depositing (or forming) the second conductive contact 124 above the first mask layer 118. In some instances, during trench etching, the etch should be able to punch-thru the second barrier layer 136, and the etch should expose the first mask layer 118.

In some instances, FIG. 7 may refer to downstream processes, operations or similar events in a semiconductor fabrication process that may be used to complete an upper metal build of the multi-layered structure 100, wherein the second mask layer 120 is formed above the device CeRAM stack.

Particular aspects of the present disclosure describe methods and/or processes for preparing and/or fabricating correlated electron materials (CEMs) films to form, for example, a correlated electron switch, such as may be utilized to form a correlated electron random access memory (CERAM), and/or logic devices, for example. Correlated electron materials, which may be utilized in the construction of CERAM devices and CEM switches, for example, may also comprise a wide range of other electronic circuit types, such as, for example, memory controllers, memory arrays, filter circuits, data converters, optical instruments, phase locked loop circuits, microwave and millimeter wave transceivers, and so forth, although claimed subject matter is not limited in scope in these respects.

In this context, a CEM switch, for example, may exhibit a substantially rapid conductive-state-to-insulative-state, which may be enabled, at least in part, by electron correlations, which modify electrical properties of the material, rather than solid-state structural phase changes, such as in response to a change from a crystalline to an amorphous state, for example. Such solid-state structural phase changes, such as from crystalline to amorphous states, for example, may bring about formation of conductive filaments in certain resistive RAM devices. In one aspect, a substantially rapid conductor-to-insulator transition in a CEM device may be responsive to a quantum mechanical phenomenon that takes place within the bulk of a material, in contrast to melting/solidification or localized filament formation, for example, in phase change and certain resistive RAM devices. Such quantum mechanical transitions between relatively conductive and relatively insulative states, and/or between a first impedance state and a second, dissimilar impedance state, for example, in a CEM device may be understood in any one of several aspects. As used herein, the terms “relatively conductive state,” “relatively lower impedance state,” and/or “metal state” may be interchangeable, and/or may, at times, be referred to as a “relatively conductive/lower-impedance state.” Likewise, the terms “relatively insulative state” and “relatively higher impedance state” may be used interchangeably herein, and/or may, at times, be referred to as a “relatively insulative/higher impedance state.” Further, in a relatively insulative/higher-impedance state, a CEM may be characterized by a range of impedances, and, in a relatively conductive/lower-impedance state, a CEM may be characterized by a second range of impedances. In embodiments, the range of impedances may be significantly dissimilar to the second range of impedances.

In an aspect, a quantum mechanical transition of a CEM between a relatively insulative/higher impedance state and a relatively conductive/lower impedance state, wherein the relatively conductive/lower impedance state is substantially dissimilar from the insulative/higher impedance state, may be understood in terms of a Mott transition. In accordance with a Mott transition, a material may switch between a relatively insulative/higher impedance state to a relatively conductive/lower impedance state if a Mott transition condition occurs. The Mott criteria may be defined by (nc)1/3 a≈0.26, wherein nc denotes a concentration of electrons, and wherein “a” denotes the Bohr radius. If a threshold carrier concentration is achieved, such that the Mott criteria is met, the Mott transition is believed to occur. Responsive to the Mott transition occurring, the state of the CEM device changes from a relatively higher resistance/higher capacitance state (e.g., a higher-impedance/insulative state) to a relatively lower resistance/lower capacitance state (e.g., a lower-impedance/conductive state) that is substantially dissimilar from the higher resistance/higher capacitance state.

In another aspect, the Mott transition may be controlled by a localization of electrons. If carriers, such as electrons, for example, are localized, a strong coulomb interaction between the carriers may split the bands of the CEM to bring about a relatively insulative (relatively higher impedance) state. If electrons are no longer localized, a weak coulomb interaction may dominate, which may give rise to a removal of band splitting. Responsive to such band splitting, a metal may transition from a relatively conductive state to a substantially dissimilar, insulative state.

Further, in an embodiment, switching from a relatively insulative/higher impedance state to a substantially dissimilar and relatively conductive/lower impedance state may enable a change in capacitance in addition to a change in resistance. For example, a CEM device may exhibit a variable resistance together with a property of variable capacitance. In other words, impedance characteristics of a CEM device may include both resistive and capacitive components. For example, in a metal state, a CEM device may comprise a relatively low electric field that may approach zero, and thus may exhibit a substantially low capacitance, which may likewise approach zero.

Similarly, in a relatively insulative/higher impedance state, which may be brought about by a higher density of bound or correlated electrons, an external electric field may be capable of penetrating a CEM and, therefore, the CEM may exhibit higher capacitance based, at least in part, on additional charges stored within the CEM. Thus, for example, a transition from a relatively insulative/higher impedance state to a substantially dissimilar and relatively conductive/lower impedance state in a CEM device may result in changes in both resistance and capacitance, at least in particular embodiments. Such a transition may bring about additional measurable phenomena, and claimed subject matter is not limited in this respect.

In an embodiment, a device formed from a CEM may exhibit switching of impedance states responsive to a Mott-transition in a majority of the volume of the CEM comprising a CEM-based device. In an embodiment, a CEM may form a “bulk switch.” As used herein, the term “bulk switch” refers to at least a substantial volume of a CEM switching a device's impedance state, such as in response to a Mott-transition. For example, in an embodiment, substantially all CEM of a device may switch between a relatively insulative/higher impedance state and a relatively conductive/lower impedance state (e.g., a “metal” or “metallic state”) responsive to a Mott transition, or from a relatively conductive/lower impedance state to a relatively insulative/higher impedance state responsive to a reverse Mott transition.

In implementations, a CEM may comprise one or more “D block” elements or compounds of “D block” elements, which correspond to transition metals or transition metal oxides (TMOs). CEM devices may also be implemented utilizing one or more “F block” elements or compounds of “F block” elements. A CEM may comprise one or more rare earth elements, oxides of rare earth elements, oxides comprising one or more rare earth transition metals, perovskites, yttrium, and/or ytterbium, or any other compounds comprising metals from the lanthanide or actinide series of the periodic table of the elements, for example, and claimed subject matter is not limited in scope in this respect. A CEM may additionally comprise a dopant, such as a carbon-containing dopant and/or a nitrogen-containing dopant, wherein the atomic concentration (e.g., of carbon or nitrogen) comprise between about 0.1% to about 15.0%. As the term is used herein, a “D block” element means an element comprising scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), rutherfordium (Rf), dubnium (Db), seaborgium (Sg), bohrium (Bh), hassium (Hs), meitnerium (Mt), darmstadtium (Ds), roentgenium (Rg) or copernicium (Cn), or any combination thereof. A CEM formed from or comprising an “F block” element of the periodic table of the elements means a CEM comprising a metal or metal oxide, wherein the metal is from the F block of the periodic table of the elements, which may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), actinium (Ac), thorium (Th), protactinium (Pa), uranium (U), neptunium (Np), plutonium (Pu), americium (Am), berkelium (Bk), californium (Cf), einsteinium (Es), fermium (Fm), mendelevium (Md), nobelium (No) or lawrencium (Lr), or any combination thereof.

FIG. 8A is an illustration of an embodiment 800 of a current density (J) versus an applied voltage (VEXT) for a device formed from a CEM. At least partially in response to a voltage applied to terminals of a CEM device, for example, during a “write operation,” the CEM device may be placed into a relatively low-impedance/conductive state or a relatively high-impedance/insulative state. For example, application of a voltage Vset and a current density Jset may enable a transition of the CEM device to a relatively low-impedance/conductive state. Conversely, application of a voltage Vreset and a current density Jreset may enable a transition of the CEM device to a relatively high-impedance/insulative state. As shown in FIG. 8A, reference designator 810 illustrates the voltage range that may separate Vset from Vreset. Following placement of the CEM device into a high-impedance state/insulative or into a low-impedance/conductive state, the particular state of the CEM device may be detected by application of a voltage Vread (e.g., during a read operation) and detection of a current or current density at terminals of the CEM device (e.g., utilizing read window 807).

According to an embodiment, the CEM device characterized in FIG. 8A may comprise any transition metal oxide (TMO), such as, for example, perovskites, Mott insulators, charge exchange insulators, and Anderson disorder insulators, as well as any compound or material comprising a D block or F block element. In one aspect, the CEM device of FIG. 8A may comprise other types of TMO switching materials, though it should be understood that these are exemplary only and are not intended to limit claimed subject matter. Nickel oxide (NiO) is disclosed as one particular TMO material. NiO materials discussed herein may be doped with substitutional ligands, such as carbon-containing materials (e.g., carbonyl (CO)4), or nitrogen-containing materials, such as ammonia (NH3), for example, which may establish and/or stabilize material properties and/or enable a P-type operation in which a CEM may be more conductive when placed into a low-impedance/conductive state. Thus, in another particular example, NiO doped with substitutional ligands may be expressed as NiO:Lx, where Lx may indicate a ligand element or compound and x may indicate a number of units of the ligand for one unit of NiO. A value of x may be determined for any specific ligand and any specific combination of ligand with NiO or with any other transition metal compound by balancing valences. Other dopant ligands, which may enable or increase conductivity in a low-impedance/conductive state in addition to carbonyl may include: nitrosyl (NO), an isocyanide (RNC wherein R is H, C1-C6 alkyl or C6-C10 aryl), a phosphine (R3P wherein R is C1-C6 alkyl or C6-C10 aryl) for example, triphenylphosphine (PPh3), an alkyne (e.g., ethyne) or phenanthroline (C12H8N2), bipyridine (C10H8N2), ethylenediamine (C2H4(NH2)2), acetonitrile (CH3CN), fluoride (F), chloride (CI), bromide (Br), cyanide (CN), sulfur (S), carbon (C), and others

In this context, a “P-type” doped CEM as referred to herein means a first type of CEM comprising a particular molecular dopant that exhibits increased electrical conductivity, relative to an undoped CEM, when the CEM is operated in a relatively low-impedance/conductive state. Introduction of a substitutional ligand, such as CO and NH3, may operate to enhance the P-type nature of a NiO-based CEM, for example. Accordingly, an attribute of P-type operation of a CEM may include, at least in particular embodiments, an ability to tailor or customize electrical conductivity of a CEM, operated in a relatively low-impedance/conductive state, by controlling an atomic concentration of a P-type dopant in a CEM. In particular embodiments, an increased atomic concentration of a P-type dopant may enable increased electrical conductivity of a CEM, although claimed subject matter is not limited in this respect. In particular embodiments, changes in atomic concentration or atomic percentage of P-type dopant in a CEM device may be observed in the characteristics of region 804 of FIG. 8A, as described herein, wherein an increase in P-type dopant brings about a steeper (e.g., more positive) slope of region 804 to indicate higher conductivity.

In this context, a “P-type” doped CEM as referred to herein means a first type of CEM comprising a particular molecular dopant that exhibits increased electrical conductivity, relative to an undoped CEM, while the CEM is operated in a relatively low-impedance/conductive state. Introduction of a substitutional ligand, such as CO and NH3, may operate to enhance the P-type nature of a NiO-based CEM, for example. Accordingly, an attribute of P-type operation of a CEM may include, at least in particular embodiments, an ability to tailor or customize electrical conductivity of a CEM, operated in a relatively low-impedance/conductive state, by controlling an atomic concentration of a P-type dopant in a CEM. In particular embodiments, an increased atomic concentration of a P-type dopant may enable increased electrical conductivity of a CEM, although claimed subject matter is not limited in this respect. In particular embodiments, changes in atomic concentration or atomic percentage of P-type dopant in a CEM device may be observed in the characteristics of region 804 of FIG. 8A, as described herein, wherein an increase in P-type dopant brings about a steeper (e.g., more positive) slope of region 804 to indicate higher conductivity.

In another embodiment, the CEM device represented by the current density versus voltage profile of FIG. 8A, may comprise other TMO materials, such as carbon-containing ligands or nitrogen-containing ligands, though it should be understood that these are exemplary only and are not intended to limit claimed subject matter. NiO, for example, may be doped with substitutional carbon- or nitrogen-containing ligands, which may stabilize switching properties in a manner similar to stabilization switching properties responsive to use of a carbon-containing dopant species (e.g., carbonyl). In particular, NiO materials disclosed herein may include nitrogen-containing molecules of the form CxHyNz (wherein x>0, y>0, z>0, and wherein at least x, y, or z comprise values >0) such as ammonia (NH3), cyano (CN—), azide ion (N3—) ethylene diamine (C2H8N2), phen(1,10-phenanthroline) (1.0 nm and about 50.0 C12H8N2), 2,2′bipyridine (C10,H8N2), ethylenediamine ((C2H4(NH2)2), pyridine (C5H5N), acetonitrile (CH3CN), and cyanosulfanides such as thiocyanate (NCS—), for example. NiO switching materials disclosed herein may include members of an oxynitride family (NxOy, wherein x and y comprise whole numbers, and wherein x>0 and y>0 and at least x or y comprise values >0), which may include, for example, nitric oxide (NO), nitrous oxide (N2O), nitrogen dioxide (NO2), or precursors with an NO3— ligand.

In accordance with FIG. 8A, if sufficient bias voltage is applied (e.g., exceeding a band-splitting potential) and the aforementioned Mott condition is satisfied (e.g., injected electron holes are of a population comparable to a population of electrons in a switching region, for example), a CEM device may switch between a relatively low-impedance/conductive state to a relatively high-impedance/insulative state, for example, responsive to a Mott transition. This may correspond to point 808 of the voltage versus current density profile of FIG. 8A. At, or suitably near this point, electrons are no longer screened and become localized near the metal ion. This correlation may result in a strong electron-to-electron interaction potential, which may operate to split the bands to form a relatively high-impedance/insulative material. If the CEM device comprises a relatively high-impedance/insulative state, current may be generated by transportation of electron holes. Consequently, if a threshold voltage is applied across terminals of the CEM device, electrons may be injected into a metal-insulator-metal (MIM) diode over the potential barrier of the MIM device. In certain embodiments, injection of a threshold current of electrons, at a threshold potential applied across terminals of a CEM device, may perform a “set” operation, which places the CEM device into a low-impedance/conductive state. In a low-impedance/conductive state, an increase in electrons may screen incoming electrons and remove a localization of electrons, which may operate to collapse the band-splitting potential, thereby giving rise to the low-impedance/conductive state.

In accordance with particular embodiments, current in a CEM device may be controlled by an externally applied “compliance” condition, which may be determined at least partially on the basis of an applied external current, which may be limited during a write operation, for example, to place the CEM device into a relatively high-impedance/insulative state. This externally applied compliance current may, in some embodiments, also set a condition of a current density for a subsequent reset operation to place the CEM device into a relatively high-impedance/insulative state. As shown in the particular implementation of FIG. 8A, a voltage Vset may be applied during a write operation to give rise to a current density Jcomp, such as at point 816, to place the CEM device into a relatively low-impedance/conductive state, which may determine a compliance condition for placing the CEM device into a relatively high-impedance/insulative state in a subsequent write operation. As shown in FIG. 8A, the CEM device may be subsequently placed into a low-impedance/conductive state by application of an externally applied voltage (Vreset), which may give rise to a current density Jreset Jcomp at a voltage referenced by 808 in FIG. 8A.

In embodiments, compliance may set a number of electrons in a CEM device that may be “captured” by holes for the Mott transition. In other words, a current applied in a write operation to place a CEM device into a relatively low-impedance/conductive memory state may determine a number of holes to be injected to the CEM device for subsequently transitioning the CEM device to a relatively high-impedance/insulative state.

As pointed out above, a reset condition may occur in response to a Mott transition at point 808. As pointed out above, such a Mott transition may give rise to a condition in a CEM device in which a concentration of electrons n approximately equals, or becomes at least comparable to, a concentration of electron holes p. This condition may be modeled according to expression (1) as follows:

$${λ}_{T F} {n}^{\frac{1}{3}} = C \text{∼} 0.26 \\ n = {( \frac{C}{{λ}_{T F}} )}^{3} \qquad ( 1 )$$

In expression (1), λTF corresponds to a Thomas Fermi screening length, and C is a constant.

According to an embodiment, a current or current density in region 804 of the voltage versus current density profile shown in FIG. 8A, may exist in response to injection of holes from a voltage signal applied across terminals of a CEM device, which may correspond to P-type operation of the CEM device. Here, injection of holes may meet a Mott transition criterion for the low-impedance/conductive state to high-impedance/insulative state transition at current IMI as a threshold voltage VMI is applied across terminals of a CEM device. This may be modeled according to expression (2) as follows:

$${I}_{M I} ( {V}_{M I} ) = \frac{dQ ( {V}_{M I} )}{d t} \approx \frac{Q ( {V}_{M I} )}{t} \\ Q ( {V}_{M I} ) = qn ( {V}_{M I} ) \qquad ( 2 )$$

In expression (2), Q(VMI) corresponds to the charged injected (holes or electrons) and is a function of an applied voltage. Injection of electrons and/or holes to enable a Mott transition may occur between bands and in response to threshold voltage VMI, and threshold current IMI. By equating electron concentration n with a charge concentration to bring about a Mott transition by holes injected by IMI in expression (2) according to expression (1), a dependency of such a threshold voltage VMI on Thomas Fermi screening length λTF may be modeled according to expression (3), as follows:

$${I}_{M I} ( {V}_{M I} ) = \frac{Q ( {V}_{M I} )}{t} = \frac{qn ( {V}_{M I} )}{t} = \frac{q}{t} {( \frac{C}{{λ}_{T F}} )}^{3} \\ {J}_{reset} ( {V}_{M I} ) = {J}_{MI} ( {V}_{M I} ) = \frac{{I}_{MI} ( {V}_{MI} )}{{A}_{CEM}} = \frac{q}{{A}_{CEM} t} {( \frac{C}{{λ}_{T F} ( {V}_{MI} )} )}^{3} \qquad ( 3 )$$

In expression (3), ACEM is a cross-sectional area of a CEM device; and make the italics) may represent a current density through the CEM device to be applied to the CEM device at a threshold voltage VMI, which may place the CEM device into a relatively high-impedance/insulative state.

According to an embodiment, a CEM device, which may be utilized to form a CEM switch, a CERAM memory device, or a variety of other electronic devices comprising one or more correlated electron materials, may be placed into a relatively low-impedance/conductive memory state, such as by transitioning from a relatively high-impedance/insulative state, for example, via injection of a sufficient quantity of electrons to satisfy a Mott transition criteria. In transitioning a CEM device to a relatively low-impedance/conductive state, if enough electrons are injected and the potential across the terminals of the CEM device overcomes a threshold switching potential (e.g., Vset), injected electrons may begin to screen. As previously mentioned, screening may operate to unlocalize double-occupied electrons to collapse the band-splitting potential, thereby bringing about a relatively low-impedance/conductive state.

In particular embodiments, changes in impedance states of a CEM device, may be brought about by “back-donation” of electrons of compounds comprising NixOy (wherein the subscripts “x” and “y” comprise whole numbers). As the term is used herein, “back-donation” refers to a supplying of one or more electrons (e.g., increased electron density) to a transition metal, transition metal oxide, or any combination thereof (e.g., to an atomic orbital of a metal), by an adjacent molecule of a lattice structure, such as a ligand or dopant. Back-donation also refers to reversible donation of electrons (e.g., an increase electron density) from a metal atom to an unoccupied π-antibonding orbital on a ligand or dopant. Back-donation may permit a transition metal, transition metal compound, transition metal oxide, or a combination thereof, to maintain an ionization state that is favorable to electrical conduction under an influence of an applied voltage. In certain embodiments, back-donation in a CEM, for example, may occur responsive to use of carbon-containing dopants, such as carbonyl (CO)4, or a nitrogen-containing dopant species, such as ammonia (NH3), ethylene diamine (C2H8N2), or members of an oxynitride family (NxOy), for example, which may permit a CEM to exhibit a property in which electrons are controllably, and reversibly, “donated” to a conduction band of the transition metal or transition metal oxide, such as nickel, for example, during operation of a device or circuit comprising a CEM. Back donation may be reversed, for example, in a nickel oxide material (e.g., NiO:CO or NiO:NH3), thereby permitting the nickel oxide material to switch to exhibiting a substantially dissimilar impedance property, such as a high-impedance/insulative property, during device operation.

Thus, in this context, an electron back-donating material refers to a material that exhibits an impedance switching property, such as switching from a first impedance state to a substantially dissimilar second impedance state (e.g., from a relatively low impedance state to a relatively high impedance state, or vice versa) based, at least in part, on influence of an applied voltage to control donation of electrons, and reversal of the electron donation, to and from a conduction band of the CEM.

In some embodiments, by way of back-donation, a CEM switch comprising a transition metal, transition metal compound, or a transition metal oxide, may exhibit low-impedance/conductive properties if the transition metal, such as nickel, for example, is placed into an oxidation state of 2+ (e.g., Ni2+ in a material, such as NiO:CO or NiO:NH3). Conversely, electron back-donation may be reversed if a transition metal, such as nickel, for example, is placed into an oxidation state of 1+ or 3+. Accordingly, during operation of a CEM device, back-donation may result in “disproportionation,” which may comprise substantially simultaneous oxidation and reduction reactions, substantially in accordance with expression (4), below:

2Ni2+→Ni1++Ni3+ (4)

Such disproportionation, in this instance, refers to formation of nickel ions as Ni1++ Ni3+ as shown in expression (4), which may bring about, for example, a relatively high-impedance/insulative state during operation of the CEM device. In an embodiment, a dopant such as a carbon-containing ligand, carbonyl (CO) or a nitrogen-containing ligand, such as an ammonia molecule (NH3), may permit sharing of electrons during operation of a CEM device so as to give rise to the disproportionation reaction of expression (4), and its reversal, substantially in accordance with expression (5), below:

Ni1++Ni3+→2Ni2+ (5)

As previously mentioned, reversal of the disproportionation reaction, as shown in expression (5), permits nickel-based CEM to return to a relatively low-impedance/conductive state.

In embodiments, depending on a molecular concentration of NiO:CO or NiO:NH3, for example, which may vary from values approximately in the range of an atomic percentage of about 0.1% to about 15.0%, Vreset and Vset, as shown in FIG. 8A, may vary approximately in the range of about 0.1 V to about 10.0 V subject to the condition that Vset≥Vreset. For example, in one possible embodiment, Vreset may occur at a voltage approximately in the range of about 0.1 V to about 1.0 V, and Vset may occur at a voltage approximately in the range of about 1.0 V to about 2.0 V, for example. It should be noted, however, that variations in Vset and Vreset may occur based, at least in part, on a variety of factors, such as atomic concentration of an electron back-donating material, such as NiO:CO or NiO:NH3 and other materials present in the CEM device, as well as other process variations, and claimed subject matter is not limited in this respect.

FIG. 8B is an illustration of an embodiment 850 of a switching device comprising a CEM and a schematic diagram of an equivalent circuit of a CEM switch. As previously mentioned, a correlated electron device, such as a CEM switch, a CERAM array, or other type of device utilizing one or more correlated electron materials may comprise a variable or complex impedance device that may exhibit characteristics of both variable resistance and variable capacitance. In other words, impedance characteristics for a CEM variable impedance device, such as a device comprising conductive film 860, CEM film 870, and conductive overlay 880, may depend at least in part on resistance and capacitance characteristics of the device if measured across device terminals 822 and 830. In an embodiment, an equivalent circuit for a variable impedance device may comprise a variable resistor, such as variable resistor 826, in parallel with a variable capacitor, such as variable capacitor 828. Of course, although a variable resistor 826 and variable capacitor 828 are depicted in FIG. 8B as comprising discrete components, a variable impedance device, such as device of embodiment 850, may comprise a substantially homogenous CEM film and claimed subject matter is not limited in this respect.

Table 1 below depicts an example truth table for an example variable impedance device, such as the device of embodiment 850.

TABLE 1
Correlated Electron Switch Truth Table

| Resistance | Capacitance | Impedance |
|---|---|---|
| R_{high}(V_{applied}) | C_{high}(V_{applied}) | Z_{high}(V_{applied}) |
| R_{low}(V_{applied}) | C_{low}(V_{applied})~0 | Z_{low}(V_{applied}) |

In an embodiment, Table 1 shows that a resistance of a variable impedance device, such as the device of embodiment 850, may transition between a low-impedance/conductive state and a substantially dissimilar, high-impedance/insulative state as a function at least partially dependent on a voltage applied across a CEM device. In an embodiment, an impedance exhibited at a low-impedance/conductive state may be approximately in the range of 10.0-100,000.0 times lower than an impedance exhibited in a high-impedance/insulative state. In other embodiments, an impedance exhibited at a low-impedance/conductive state may be approximately in the range of 5.0 to 10.0 times lower than an impedance exhibited in a high-impedance/insulative state, for example. It should be noted, however, that claimed subject matter is not limited to any particular impedance ratios between high-impedance/insulative states and low-impedance/conductive states. Table 1 shows that a capacitance of a variable impedance device, such as the device of embodiment 850, may transition between a lower capacitance state, which, in an example embodiment, may comprise approximately zero (or negligible) capacitance, and a higher capacitance state that is a function, at least in part, of a voltage applied across a CEM device.

In certain embodiments, atomic layer deposition may be utilized to form or to fabricate films comprising NiO materials, such as NiO:CO or NiO:NH3. In this context, a “layer” as the term is used herein means a sheet or coating of material, which may be disposed on or over an underlying formation, such as a conductive or insulating substrate. For example, a layer deposited on an underlying substrate by way of an atomic layer deposition process may comprise a thickness dimension comparable to that of a single atom, which may comprise, for example, a fraction of an angstrom (e.g., 0.6 Å). However, in other embodiments, a layer may encompass a sheet or coating comprising a thickness dimension greater than that of a single atom depending, for example, on a process utilized to fabricate films comprising a CEM film. Additionally, a “layer” may be oriented horizontally (e.g. a “horizontal” layer), oriented vertically (e.g., a “vertical” layer), or may be positioned in any other orientation, such as diagonally, for example. In embodiments, a CEM film may comprise a sufficient number of layers, to permit electron back-donation during operation of a CEM device in a circuit environment, for example, to give rise to a low-impedance/conductive state. During operation in a circuit environment, for example, electron back-donation may be reversed so as to give rise to a substantially dissimilar impedance state, such as a high-impedance/insulative state, for example.

In this context, a “substrate” as used herein means a structure comprising a surface that enables materials, such as materials having particular electrical properties (e.g., conductive properties, insulative properties, etc.) to be deposited or placed on or over the substrate. For example, in a CEM-based device, conductive film 860 may operate to convey an electrical current to a CEM film in contact with conductive film 860. A conductive film, such as conductive film 860, for example, may comprise a titanium-based and/or titanium-containing material, such as titanium nitride (TiN), fabricated in layers, for example, for use in a CEM switch other type of CEM-based device. In other embodiments, conductive film 860 may comprise other types of conductive materials, such as titanium nitride, platinum, copper, aluminum, cobalt, nickel, tungsten, tungsten nitride, cobalt silicide, ruthenium oxide, chromium, gold, palladium, indium tin oxide, tantalum, silver, iridium, or any combination thereof, and claimed subject matter is not limited to any particular composition of conductive film material.

In embodiments, in which conductive film 860 comprises titanium nitride, for example, conductive film 860 may be formed utilizing precursors such as titanium tetrachloride (TiCl4), which may comprise chlorine as a potential dopant species as the chlorine atoms diffuse into a CEM. In another embodiment, a TiN conductive film may be formed utilizing tetrakis dimethylamido titanium (TDMAT), tetrakis diethylamido titanium (TDEAT), and/or titanium isopropoxide (TTIP), which may comprise carbon as a dopant species as carbon atoms diffuse into the CEM. It should be noted that titanium-based and/or titanium-containing precursor materials may comprise dopant species in addition to chlorine and/or carbon and claimed subject matter is not limited in this respect. Precursors may be used with nitrogen (e.g., co-flow) as a dopant species in the form of NH3.

In other embodiments, conductive film 860 may comprise a tantalum-based and/or a tantalum-containing material, such as tantalum nitride (TaN), formed in layers, for use in a CERAM device or other type of CEM-based device. In embodiments, a TaN conductive film may be formed utilizing precursors such as pentakisdimethylamido tantalum (PDMAT), which may comprise carbon as a dopant species. In another embodiment, a TaN conductive film may be formed utilizing tantalum ethoxide (TAETO), which may also comprise carbon as a dopant species. In another embodiment, a TaN conductive film may be formed utilizing tantalum pentachloride (TaCl5), which may comprise chlorine as a dopant species. It should be noted that tantalum-based and/or tantalum-containing precursor materials may comprise dopant species in addition to chlorine and/or carbon and claimed subject matter is not limited in this respect. Precursors may be used with nitrogen (e.g., co-flow) as a dopant species in the form of NH3.

In other embodiments, conductive film 860 may comprise a tungsten-based and/or a tungsten-containing material formed in layers, such as tungsten-nitride (WN), for example, for use in a CERAM device or other type of CEM-based device. In embodiments, a WN conductive film may be formed utilizing precursors such as tungsten hexacarbonyl (W(CO)6) and/or cyclopentadienyltungsten(II) tricarbonyl hydride, both of which may comprise carbon as a dopant species. In another embodiment, a WN conductive film may be formed utilizing triamminetungsten tricarbonyl ((NH3)3W(CO)3) and/or tungsten pentacarbonyl methylbutylisonitrile (W(CO)5(C5H11NC), both of which may comprise carbon or nitrogen as a dopant species. It should be noted that tungsten-based and/or tungsten precursor materials may comprise dopant species in addition to nitrogen and/or carbon and claimed subject matter is not limited in this respect. Precursors may be used with nitrogen (e.g., co-flow) as a dopant species in the form of NH3.

In particular embodiments, formation of CEM films on or over a conductive film may utilize two or more precursors to deposit components of, for example, NiO:CO or NiO:NH3, or other transition metal oxide, transition metal, or combination thereof, onto a conductive material such as a conductive film. In an embodiment, layers of a CEM film may be deposited utilizing separate precursor molecules, AX and BY, according to expression (6A), below:

AX(gas)+BY(gas)=AB(solid)+XY(gas) (6A)

Wherein “A” of expression (6A) corresponds to a transition metal, transition metal compound, transition metal oxide, or any combination thereof. In embodiments, a transition metal oxide may comprise nickel, but may comprise other transition metals, transition metal compounds, and/or transition metal oxides, such as aluminum, cadmium, chromium, cobalt, copper, gold, iron, manganese, mercury, molybdenum, nickel palladium, rhenium, ruthenium, silver, tantalum, tin, titanium, vanadium, yttrium, and zinc (which may be linked to an anion, such as oxygen or other types of ligands), or combinations thereof, although claimed subject matter is not limited in scope in this respect. In particular embodiments, compounds that comprise more than one transition metal oxide may also be utilized, such as yttrium titanate (YTiO3).

In embodiments, “X” of expression (6A) may comprise a ligand, such as organic ligand, comprising amidinate (AMD), dicyclopentadienyl (Cp)2, diethylcyclopentadienyl (EtCp)2, Bis(2,2,6,6-tetramethylheptane-3,5-dionato) ((thd)2), acetylacetonate (acac), bis(methylcyclopentadienyl) ((CH3C5H4)2), dimethylglyoximate (dmg)2, 2-am ino-pent-2-en-4-onato (apo)2, (dmamb)2 where dmamb=1-dimethylamino-2-methyl-2-butanolate, (dmamp)2 where dmamp=1-dimethylamino-2-methyl-2-propanolate, Bis(pentamethylcyclopentadienyl) (C5(CH3)5)2 and carbonyl (CO)4. Accordingly, in some embodiments, nickel-based precursor AX may comprise, for example, nickel amidinate (Ni(AMD)), nickel dicyclopentadienyl (Ni(Cp)2), nickel diethylcyclopentadienyl (Ni(EtCp)2), Bis(2,2,6,6-tetramethylheptane-3,5-dionato)Ni(II) (Ni(thd)2), nickel acetylacetonate (Ni(acac)2), bis(methylcyclopentadienyl)nickel (Ni(CH3C5H4)2, Nickel dimethylglyoximate (Ni(dmg)2), nickel 2-amino-pent-2-en-4-onato (Ni(apo)2), Ni(dmamb)2 where dmamb=1-dimethylamino-2-methyl-2-butanolate, Ni(dmamp)2 where dmamp=1-dimethylamino-2-methyl-2-propanolate, Bis(pentamethylcyclopentadienyl) nickel (Ni(C5(CH3)5)2, and nickel carbonyl (Ni(CO)4), just to name a few examples.

However, in particular embodiments, a dopant operating as an electron back-donating species in addition to precursors AX and BY may be utilized to form layers of a TMO film. An electron back-donating species, which may co-flow with precursor AX, may permit formation of electron back-donating compounds, substantially in accordance with expression (6B), below. In embodiments, a dopant species or a precursor to a dopant species, such as carbonyl (CO)4, ammonia (NH3), methane (CH4), carbon monoxide (CO), or other precursors and/or dopant species may be utilized to provide electron back-donating ligands listed above. Thus, expression (6A) may be modified to include an additional dopant ligand comprising an electron back-donating material substantially in accordance with expression (6B), below:

AX(gas)+(NH3 or other ligand comprising nitrogen)+BY(gas)=AB:NH3(solid)+XY(gas) (6B)

It should be noted that concentrations, such as atomic concentrations, of precursors, such as AX, BY, and NH3 (or other ligand comprising nitrogen) of expressions (6A) and (6B) may be adjusted to give rise to a final atomic concentration of nitrogen-containing or carbon-containing dopant to permit electron back-donation in a fabricated CEM device. As referred to herein, the term “dopant atomic concentration” means the concentration of atoms in the finished material that derive from the substitutional ligand. For example, in the case in which the substitutional ligand is CO, the atomic concentration of CO in percentage terms comprises the total number of carbon atoms that comprise the material film divided by the total number of atoms in the material film, multiplied by 100.0. In another example, for the case in which the substitutional ligand is NH3, the atomic concentration of NH3 comprises the total number of nitrogen atoms that comprise the material film divided by the total number of atoms in the material film, multiplied by 100.0.

In particular embodiments, nitrogen- or carbon-containing dopants may comprise ammonia (NH3), carbon monoxide (CO), or carbonyl (CO)4 in an atomic concentration of between about 0.1% and about 15.0%. In particular embodiments, atomic concentrations of dopants, such as NH3 and CO, may comprise a more limited range of atomic concentrations such as, for example, between about 1.0% and about 15.0%. However, claimed subject matter is not necessarily limited to the above-identified precursors and/or atomic concentrations. It should be noted that claimed subject matter is intended to embrace all such precursors and atomic concentrations of dopants utilized in atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, or the like, utilized in fabrication of CEM devices from TMO materials. In expressions (6A) and (6B), “BY” may comprise an oxidizer, such as water (H2O), oxygen (O2), ozone (O3), plasma O2, hydrogen peroxide (H2O2). In other embodiments, “BY” may comprise CO, O2+ (CH4), or nitric oxide (NO)+ water (H2O) or an oxynitride or carbon-containing a gaseous oxidizing or oxynitridizing agent. In other embodiments, plasma may be used with an oxidizer (BY) to form oxygen radicals (O*). Likewise, plasma may be used with a dopant species to form an activated species to control dopant concentration in a CEM.

In particular embodiments, such as embodiments utilizing atomic layer deposition, a conductive film, such as conductive film 860, may be exposed to precursors, such as AX and BY of expression (6B), as well as dopants providing electron back-donation (such as ammonia or other ligands comprising metal-nitrogen bonds, including, for example, nickel-amides, nickel-imides, nickel-amidinates, or combinations thereof) in a heated chamber, which may attain, for example, a temperature of approximately in the range of 20.0° C. to 1000.0° C., for example, or between temperatures approximately in the range of 20.0° C. and 500.0° C. in certain embodiments. In one particular embodiment, in which atomic layer deposition of NiO:NH3, for example, is performed, chamber temperature ranges approximately in the range of 20.0° C. and 400.0° C. may be utilized. Responsive to exposure to precursor gases (e.g., AX, BY, NH3, or other ligand comprising nitrogen), such gases may be purged from the heated chamber for durations approximately in the range of 0.5 seconds to 180.0 seconds, for example. It should be noted, however, that these are merely examples of potentially suitable ranges of chamber temperature and/or time and claimed subject matter is not limited in this respect.

In certain embodiments, a single two-precursor cycle (e.g., AX and BY, as described with reference to expression (6A) or a single three-precursor cycle (e.g., AX, NH3, CH4, or other ligand comprising nitrogen, carbon, or other electron back-donating dopant derived from an substitutional ligand and BY, as described with reference to expression (6B) utilizing atomic layer deposition may bring about a layer of a TMO material film comprising a thickness dimension approximately in the range of 0.6 Å to 5.0 Å per cycle). Accordingly, in one embodiment, if an atomic layer deposition process is capable of depositing layers of a TMO material film comprising a thickness dimension of approximately 0.6 Å, 800-900 two-precursor cycles may be utilized to bring about a TMO material film comprising a thickness dimension of approximately 500.0 Å. It should be noted that atomic layer deposition may be utilized to form TMO material films having other thickness dimensions, such as thickness dimensions approximately in the range of about 15.0 Å to about 1500.0 Å, for example, and claimed subject matter is not limited in this respect.

In particular embodiments, responsive to one or more two-precursor cycles (e.g., AX and BY), or three-precursor cycles (AX, NH3, CH4, or other ligand comprising nitrogen, carbon or other back-donating dopant material and BY), of atomic layer deposition, a TMO material film may be exposed to elevated temperatures, which may, at least in part, enable formation of a CEM device from a TMO material film. Exposure of the TMO material film to an elevated temperature may additionally enable activation of a back-donating dopant derived from a substitutional ligand, such as in the form of carbon monoxide, carbonyl, or ammonia, responsive to repositioning of the dopant to metal oxide lattice structures of the CEM device film.

Thus, in this context, an “elevated temperature” means a temperature at which substitutional or substitutional ligands evaporate from a TMO material film, and/or are repositioned within a TMO material film, to such an extent that the TMO material film transitions from a resistive film to a film that is capable of switching between a relatively high-impedance/insulative state to a relatively low-impedance/conductive state. For example, in certain embodiments, a TMO material film exposed to an elevated temperature within a chamber of about 100.0° C. to about 800.0° C. for a duration of about 30.0 seconds to about 120.0 minutes may permit evaporation of substitutional ligands from the TMO material film so as to form a CEM film. Additionally, in certain embodiments, a TMO material film exposed to an elevated temperature within a chamber of about 100.0° C. to about 800.0° C. for a duration of about 30.0 seconds to about 120.0 minutes may permit repositioning of substitutional ligands, for example, at oxygen vacancies within a lattice structure of a metal oxide. In particular embodiments, elevated temperatures and exposure durations may comprise more narrow ranges, such as, for example, temperatures of about 200.0° C. to about 500.0° C. for about 1.0 minute to about 60.0 minutes, for example, and claimed subject matter is not limited in these respects.

In particular embodiments, a CEM device manufactured in accordance with the above-described process may exhibit a “born on” property in which the device exhibits relatively low impedance (relatively high conductivity) immediately following fabrication of the device. Accordingly, if a CEM device is integrated into a larger electronics environment, for example, at initial activation a relatively small voltage applied to a CEM device may permit a relatively high current flow through the CEM device, as shown by region 804 of FIG. 8A. For example, as previously described herein, in at least one possible embodiment, Vreset may occur at a voltage approximately in the range of about 0.1 V to about 1.0 V, and Vset may occur at a voltage approximately in the range of about 1.0 V to about 2.0 V, for example. Accordingly, electrical switching voltages operating in a range of about 2.0 V, or less, may permit a memory circuit, for example, to write to a CERAM memory device, to read from a CERAM memory device, or to change state of a CERAM switch, for example. In embodiments, such relatively low voltage operation may reduce complexity, cost, and may provide other advantages over competing memory and/or switching device technologies.

In particular embodiments, two or more CEM devices may be formed within a particular layer of an integrated circuit at least in part by atomic layer deposition of a CEM. In a further embodiment, one or more of a plurality of correlated electron switch devices of a first correlated electron switch material and one or more of a plurality of correlated electron switch devices of a second correlated electron switch material may be formed, at least in part, by a combination of blanket deposition and selective epitaxial deposition. Additionally, in an embodiment, first and second access devices may be positioned substantially adjacent to first and second CEM devices, respectively.

In a further embodiment, one or more of a plurality of CEM devices may be positioned within two or more levels of an integrated circuit at one or more intersections of electrically conductive metal layers of a first level and electrically conductive metal layers of a second level, which may be positioned over the first level of conductive metal layers. In this context a “metal layer” as the term is used herein, means a conductor that routes an electrical current from a first location to a second location of a layer of a multi-level CEM switching device. For example, a conductive metal layer may transport electrical current to or from an access device located at an intersection of a conductive metal layer of first level and a conductive metal layer of the second level. In certain embodiments, fabrication of a switching device formed from a multi-level CEM device, such as devices formed utilizing conductive metal layers positioned at multiple levels of a CEM switching device may be utilized in CEM-based memory devices in which conductive metal layer positioned at multiple levels may facilitate an increase in bit line density, for example. Increases in bit line density may bring about more efficient and/or more highly integrated approaches toward controlling access to memory cells of CEM-based random access memory arrays, for example.

Additionally, in this context, a “level” as the term is used herein, means a discrete surface, which a conductive metal layer may traverse, wherein the discrete surface is separated from discrete surfaces immediately above and/or immediately below, by an insulating material. For example, as described herein, a conductive metal layer traversing a first level may be separated from a conductive metal layer traversing a second level by an insulating material, such as silicon nitride. In this context, a “multi-level” switching device, as the term is used herein, means a device to perform a switching function, such as from a high-impedance/insulative state to a low-impedance state, utilizing two or more of the above-described “levels.”

As described herein, responsive to depositing one or more dopant layers on or over one or more layers of a first material, such as a transition metal, a transition metal oxide, a transition metal compound or alloy, dopant concentration of a CEM may be accurately controlled. Additionally, by depositing one or more dopant layers on or over one or more layers of a first material, localized regions of CEM may comprise differing atomic concentrations of dopants so as to provide an approach toward tailoring or customizing a dopant concentration profile. Further, dopant concentration profiles within a CEM may be increased via adjusting annealing temperatures and/or annealing durations. In addition to the above-identified advantages, particular embodiments may provide an approach toward fabricating or forming a common source electrode, which may be useful in fabricating three-dimensional structures utilized for NAND flash memory. However, claimed subject matter is not limited to the above-identified advantages.

Described herein are various implementations of a device. The device may include a multi-layered structure formed on a substrate. The multi-layered structure may have a switching layer and at least one barrier layer, and the switching layer may be formed with correlated electron material (CEM).

Described herein are various implementations of a method. The method may include forming a multi-layered structure on a substrate. The multi-layered structure may have a switching layer and at least one barrier layer. The switching layer may be formed with correlated electron material (CEM).

Described herein are various implementations of a switch structure. The switch structure may include a bottom plate layer formed on a substrate and a switching layer formed on the bottom plate layer, wherein the switching layer has correlated electron material (CEM). The switch structure may include a first top plate layer formed on the switching layer and a barrier layer formed on the first top plate layer, wherein the barrier layer is formed with an electrically conductive material. The switch structure may include at least one mask layer formed on the barrier layer.

It should be intended that subject matter of the claims not be limited to the various implementations and illustrations provided herein, but include various modified forms of those implementations including portions of implementations and combinations of elements of different implementations in accordance with the claims. It should be appreciated that in the development of any such implementation, as in any engineering or design project, numerous implementation-specific decisions should be made to achieve developers' specific goals, such as compliance with system-related and business related constraints, which may vary from one implementation to another. It should also be appreciated that such a development effort may be complex and time consuming, but would nevertheless be a routine undertaking of design, fabrication, and manufacture for those having ordinary skill to benefit from various aspects of this disclosure.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various techniques described herein, other and further implementations may be devised in accordance with the disclosure herein, which may be determined by the claims that follow.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A device, comprising:
a multi-layered structure formed on a substrate, comprising:
a switching layer formed with correlated electron material (CEM) above one or more insulation layers; and
at least one barrier layer formed above the switching layer.

2. The device of claim 1, wherein the multi-layered structure comprises a switch structure including memory element having a memory switching structure.

3. The device of claim 1, wherein the multi-layered structure comprises a correlated electron random access memory (CeRAM) structure.

4. The device of claim 1, wherein the switching layer comprises a transition metal oxide layer (TMO) layer, and wherein the correlated electron material (CEM) comprises a memory switching material.

5. The device of claim 1, wherein the switching layer comprises a nickel-oxide material that is doped with carbonyls to provide an NiOC material.

6. The device of claim 1, wherein the at least one barrier layer comprises an electrically conductive hydrogen barrier layer that inhibits hydrogen penetration into or interaction with one or more other layers of the multi-layered structure.

7. The device of claim 1, wherein the at least one barrier layer comprises an electrically conductive barrier layer, and wherein the conductive barrier layer comprises at least one of titanium-nitride, titanium-aluminum-nitride, tin-oxide and indium-tin-oxide.

8. The device of claim 1, wherein the at least one barrier layer is formed by chemical vapor deposition (CVD) or physical vapor deposition (PVD).

9. The device of claim 1, wherein the at least one barrier layer comprises a first barrier layer that is a conductor, and wherein the device further comprises a second barrier layer that is an insulator.

10. The device of claim 9, wherein the second barrier layer is formed over the multi-layered structure as an insulator that is used for encapsulating the multi-layered structure.

11. The device of claim 9, wherein the insulator comprises at least one of strontium-tantalate, bismuth-tantalate, tantalum-oxide, titanium-oxide, zirconium-oxide and aluminum-oxide.

12. The device of claim 1, wherein the substrate comprises a first conductive contact, and wherein the multi-layered structure is formed above the first conductive contact.

13. The device of claim 1, further comprising a second conductive contact formed on the multi-layered structure.

14. A method, comprising:
forming a multi-layered structure on a substrate, wherein forming the multi-layered structure includes:
forming a switching layer with correlated electron material (CEM) above one or more insulation layers; and
forming at least one barrier layer above the switching layer.

15. The method of claim 14, wherein the multi-layered structure comprises a correlated electron random access memory (CeRAM) structure.

16. The method of claim 14, wherein the switching layer comprises a transition metal oxide layer (TMO) layer, and wherein the transition metal oxide layer (TMO) layer comprises a nickel-oxide material that is doped with carbonyls to provide an NiOC material.

17. The method of claim 14, wherein the at least one barrier layer comprises an electrically conductive hydrogen barrier layer that inhibits hydrogen penetration into or interaction with one or more other layers of the multi-layered structure.

18. The method of claim 14, wherein the at least one barrier layer comprises an electrically conductive barrier layer, and wherein the conductive barrier layer comprises at least one of titanium-nitride, titanium-aluminum-nitride, tin-oxide and indium-tin-oxide.

19. The method of claim 14, wherein the at least one barrier layer comprises a first barrier layer that is a conductor, and wherein the device further comprises a second barrier layer that is an insulator, and wherein the second barrier layer is formed over the multi-layered structure as an insulator that is used for encapsulating the multi-layered structure.

20. The method of claim 19, wherein the insulator comprises at least one of strontium-tantalate, bismuth-tantalate, tantalum-oxide, titanium-oxide, zirconium-oxide and aluminum-oxide.

21. The method of claim 14, further comprising:
forming a first conductive contact in the substrate;
forming the multi-layered structure on the first conductive contact; and
forming a second conductive contact on the multi-layered structure.

22. A switch structure, comprising:
a bottom plate layer formed above one or more insulation layers formed on a substrate;
a switching layer formed on the bottom plate layer, wherein the switching layer has correlated electron material (CEM);
a first top plate layer formed on the switching layer;
a barrier layer formed on the first top plate layer, wherein the barrier layer is formed with an electrically conductive material; and
a mask layer formed on the barrier layer.

23. The switch structure of claim 22, wherein:
the multi-layered structure comprises a correlated electron random access memory (CeRAM) structure;
the switching layer comprises a transition metal oxide layer (TMO) layer, and
the transition metal oxide layer (TMO) layer comprises a nickel-oxide material that is doped with carbonyls to provide an NiOC material.

24. A switch structure, comprising:
a bottom plate layer formed on a substrate;
a switching layer formed on the bottom plate layer, wherein the switching layer has correlated electron material (CEM);
a first top plate layer formed on the switching layer;
a barrier layer formed on the first top plate layer, wherein the barrier layer is formed with an electrically conductive material; and
a mask layer formed on the barrier layer;
wherein the barrier layer comprises a first barrier layer, wherein the mask layer comprises a first mask layer, and wherein the switch structure further comprises:
a second mask layer formed on the first mask layer; and
a second barrier layer formed on the second mask layer, wherein the second mask layer is formed with an insulative material that is used for encapsulating the switch structure.

25. The switch structure of claim 24, wherein:
the first barrier layer is formed as an electrically conductive barrier layer that inhibits hydrogen penetration into or interaction with one or more other layers of the switch structure, and
the second barrier layer is formed of an insulative barrier layer that inhibits hydrogen penetration into or interaction with one or more other layers of the switch structure.
